(19) United States
(12) Patent Application Publication
(10) Pub. No.: US 2024/0222529 A1
(43) Pub. Date: Jul. 4, 2024

(54) OPTICAL SEMICONDUCTOR ELEMENT

(71) Applicant: HAMAMATSU PHOTONICS K.K., Hamamatsu-shi (JP)

(72) Inventors: Takahide YANAI, Hamamatsu-shi (JP); Daisuke IIDA, Hamamatsu-shi (JP); Asuka MISHIMA, Hamamatsu-shi (JP)

(73) Assignee: HAMAMATSU PHOTONICS K.K., Hamamatsu-shi (JP)

(21) Appl. No.: 18/390,460

(22) Filed: Dec. 20, 2023

(30) Foreign Application Priority Data
Dec. 28, 2022 (JP) 2022-212485

(51) Int. Cl. H01L 31/02; H01L 25/04; H01L 25/075; H01L 25/16; H01L 31/12

(52) U.S. Cl. CPC H01L 31/02002; H01L 25/042; H01L 25/0753; H01L 25/167; H01L 31/125

(57) ABSTRACT

An optical semiconductor element includes a substrate, a first termination cell, and a cell. A first electrode is arranged on the top surface of the first termination cell. The first termination cell and the cell are connected to each other by a wiring layer extending from the top surface of the first termination cell to the cell. The first electrode is exposed to the outside through an opening formed in an insulating layer. The wiring layer is spaced apart from the first electrode on the top surface of the first termination cell, and is electrically connected to the first electrode via a first semiconductor layer. The first portion has a contact region in contact with the first semiconductor layer. The width of the contact region is equal to or greater than the width of the opening.

### TECHNICAL FIELD

One aspect of the present disclosure relates to an optical semiconductor element.

### BACKGROUND

For example, in a light emitting element described in Japanese Unexamined Patent Publication No. 2021-125599, a plurality of mesa portions each having a light emitting layer are formed on a substrate, and adjacent mesa portions are electrically connected to each other by metal wiring.

### SUMMARY

### Technical Problem

Light emitting elements such as that described above may be used by being electrically connected to an external member by solder, for example. In this case, it is required that the light emitting element can be stably connected to the external member by solder. In addition, it is required that a current flows satisfactorily through the light emitting element.

It is an object of one aspect of the present disclosure to provide an optical semiconductor element which can be stably connected to an external member by solder and through which a current can flow satisfactorily.

### Solution to Problem

An optical semiconductor element according to one aspect of the present disclosure is [1] “an optical semiconductor element including: a substrate; and a first cell and a second cell formed on the substrate. The first cell includes at least a first semiconductor layer. The second cell is configured to generate or detect light. A first electrode electrically connected to the first semiconductor layer is arranged on a top surface of the first cell. The first cell and the second cell are electrically connected to each other by a first wiring layer extending from the top surface of the first cell to the second cell. A first insulating layer is arranged on the top surface of the first cell, and the first electrode is exposed to outside through an opening formed in the first insulating layer. The first wiring layer is spaced apart from the first electrode on the top surface of the first cell, and is electrically connected to the first electrode via the first semiconductor layer. A portion of the first wiring layer arranged on the top surface of the first cell includes a contact region in contact with the first semiconductor layer. A width of the contact region in a predetermined direction along a width direction of the first wiring layer is equal to or greater than a width of the opening in the predetermined direction”.

In the optical semiconductor element described in [1], the first wiring layer is spaced apart from the first electrode on the top surface of the first cell. If the first electrode is electrically connected to the external member by solder, a phenomenon (solder erosion, solder corrosion) in which the solder diffuses into the first electrode may occur. However, since the first wiring layer is spaced apart from the first electrode, the diffusion of solder can be restrained at the first electrode. Therefore, the diffusion of solder into the first wiring layer can be suppressed. Therefore, in this optical semiconductor element, stable connection with an external member by solder is possible. In addition, in this optical semiconductor element, the first wiring layer is spaced apart from the first electrode on the top surface of the first cell, and is electrically connected to the first electrode via the first semiconductor layer. That is, the first wiring layer is spaced apart from the first electrode to suppress the diffusion of solder into the first wiring layer, and the first wiring layer and the first electrode are electrically connected to each other via the first semiconductor layer. However, in this case, the electrical resistance may increase compared with a case where the first wiring layer is directly connected to the first electrode. In this regard, in this optical semiconductor element, the portion of the first wiring layer arranged on the top surface of the first cell includes a contact region in contact with the first semiconductor layer, and the width of the contact region in the predetermined direction along the width direction of the first wiring layer is equal to or greater than the width of the opening in the predetermined direction. Therefore, the electrical resistance can be reduced by increasing the width of the contact region in contact with the first semiconductor layer in the first wiring layer. As a result, it is possible to make a current flow satisfactorily. Therefore, according to the optical semiconductor element described in [1], stable connection with an external member by solder is possible, and it is possible to make a current flow satisfactorily.

The optical semiconductor element according to one aspect of the present disclosure may be [2] “the optical semiconductor element described in [1], in which an entire width of a portion of the first wiring layer extending from the top surface of the first cell to the second cell is equal to or greater than the width of the opening in the predetermined direction”. In this case, the electrical resistance in the first wiring layer can be further reduced, and it is possible to reduce the electrical resistance.

The optical semiconductor element according to one aspect of the present disclosure may be [3] “the optical semiconductor element described in [1] or [2], in which the first electrode includes a planned contact region with which solder comes into contact when being electrically connected to an external member, and the planned contact region has a circular shape when viewed from a thickness direction of the substrate”. For example, if the planned contact region has a rectangular shape, there is a risk that stress will concentrate at the corners. However, since the planned contact region has a circular shape, the stress can be dispersed. As a result, it is possible to suppress the occurrence of stress concentration.

The optical semiconductor element according to one aspect of the present disclosure may be [4] “the optical semiconductor element described in any one of [1] to [3], in which the first electrode includes a first layer and a second layer arranged on a side of the substrate with respect to the first layer”. In this case, it is possible to suppress the diffusion of solder into the first electrode.

The optical semiconductor element according to one aspect of the present disclosure may be [5] “the optical semiconductor element described in [4], in which the width of the contact region in the predetermined direction is equal to or greater than a width of the first layer in the predetermined direction”. In this case, the electrical resistance in the first wiring layer can be further reduced, and it is possible to make a current flow satisfactorily.

The optical semiconductor element according to one aspect of the present disclosure may be [6] “the optical semiconductor element described in [4] or [5], in which the first wiring layer has the same layer structure as the second layer of the first electrode”. In this case, for example, the first wiring layer and the second layer of the first electrode can be formed simultaneously. As a result, the first wiring layer and the first electrode can be formed easily.

The optical semiconductor element according to one aspect of the present disclosure may be [7] “the optical semiconductor element described in any one of [1] to [6], in which the first electrode is formed of a material containing at least Au”. When the first electrode is formed of a material containing Au, solder is likely to diffuse into the first electrode. However, according to this optical semiconductor element, even in such a case, the diffusion of solder into the first wiring layer can be suppressed.

The optical semiconductor element according to one aspect of the present disclosure may be [8] “the optical semiconductor element described in any one of [1] to [7], in which the second cell includes an optical layer that is an active layer for generating light or an absorption layer for absorbing light, a second semiconductor layer arranged on a side opposite to the substrate with respect to the optical layer, and a third semiconductor layer arranged on a side of the substrate with respect to the optical layer”. In this case, light can be appropriately generated or detected by the second cell.

The optical semiconductor element according to one aspect of the present disclosure may be [9] “the optical semiconductor element described in [8], in which a layer structure of the first cell is different from a layer structure of the second cell”. In this case, it is possible to improve the degree of freedom in designing the layer structure of the first cell.

The optical semiconductor element according to one aspect of the present disclosure may be [10] “the optical semiconductor element described in [8], in which a layer structure of the first cell is the same as a layer structure of the second cell”. In this case, it is possible to reduce the difference in height between the first cell and the second cell, and the optical semiconductor element can be easily mounted.

The optical semiconductor element according to one aspect of the present disclosure may be [11] “the optical semiconductor element described in any one of [1] to [10], in which each of the first cell and the second cell has a mesa structure including a side surface inclined with respect to a thickness direction of the substrate”. According to this optical semiconductor element, even when each of the first cell and the second cell has such a mesa structure, stable connection with an external member by solder is possible.

The optical semiconductor element according to one aspect of the present disclosure may be [12] “the optical semiconductor element described in any one of [1] to [11], in which a second insulating layer is arranged between the first wiring layer and a side surface of the first cell, and the second insulating layer is provided so as to reach the top surface of the first cell”. In this case, the first wiring layer can be reliably insulated on the side surface of the first cell.

The optical semiconductor element according to one aspect of the present disclosure may be [13] “the optical semiconductor element described in any one of [1] to [12] further including a third cell formed on the substrate, in which the third cell is configured to generate or detect light and is electrically connected to the second cell by a second wiring layer, and the width of the contact region in the predetermined direction is larger than a width of a portion of the second wiring layer between the second cell and the third cell”. In this case, the width of the contact region in contact with the first semiconductor layer in the first wiring layer can be increased, and it is possible to reduce the electrical resistance.

The optical semiconductor element according to one aspect of the present disclosure may be [14] “the optical semiconductor element described in [13], in which an entire width of a portion of the first wiring layer extending from the top surface of the first cell to the second cell is larger than the width of the portion of the second wiring layer between the second cell and the third cell”. In this case, the electrical resistance in the first wiring layer can be further reduced, and it is possible to make a current flow satisfactorily.

The optical semiconductor element according to one aspect of the present disclosure may be [15] “the optical semiconductor element described in [13] or [14], in which the first wiring layer includes an extending portion that extends so as to surround an outer edge of the second cell when viewed from the thickness direction of the substrate”. In this case, since the extending portion of the first wiring layer extends so as to surround the outer edge of the second cell, a current can efficiently flow through the second cell.

The optical semiconductor element according to one aspect of the present disclosure may be [16] “the optical semiconductor element described in [15], in which a portion of the second wiring layer between the second cell and the third cell does not overlap the extending portion of the first wiring layer when viewed from the thickness direction of the substrate”. In this case, it is possible to avoid a situation in which the first wiring portion and the second wiring portion overlap each other to generate a capacitance.

The optical semiconductor element according to one aspect of the present disclosure may be [17] “the optical semiconductor element described in any one of [1] to [16], in which the first cell and the second cell are spaced apart from each other by a groove portion formed in the substrate”. In this case, the first cell and the second cell can be spatially separated from each other.

The optical semiconductor element according to one aspect of the present disclosure may be [18] “the optical semiconductor element described in any one of [1] to [17], in which the first cell has the same shape as the second cell when viewed from the thickness direction of the substrate”. In this case, it is possible to prevent power from concentrating on the first cell or the second cell.

The optical semiconductor element according to one aspect of the present disclosure may be [19] “the optical semiconductor element described in any one of [1] to [18], in which the first electrode includes a planned contact region with which solder comes into contact when being electrically connected to an external member, a third insulating layer is arranged on the first insulating layer and the first electrode is exposed to outside through an opening formed in the third insulating layer, and the planned contact region is formed by a portion of the first electrode exposed from the opening formed in the third insulating layer”. In this case, the first electrode can be reliably insulated.

The optical semiconductor element according to one aspect of the present disclosure may be [20] “the optical semiconductor element described in any one of [1] to [19], in which a distance from a portion of the first wiring layer arranged on the top surface of the first cell to the first electrode is smaller than a width of the opening in the predetermined direction”. In this case, it is possible to make a current flow satisfactorily between the first wiring layer and the first electrode.

According to one aspect of the present disclosure, it is possible to provide an optical semiconductor element which can be stably connected to an external member by solder and through which a current can flow satisfactorily.

### BRIEF DESCRIPTION OF THE DRAWINGS

FIG. 1 is a plan view of an optical semiconductor element according to an embodiment;

FIG. 2 is a partially enlarged view of FIG. 1;

FIG. 3 is a cross-sectional view taken along the line III-III of FIG. 1;

FIG. 4 is a diagram for explaining the cross-sectional structure of the optical semiconductor element;

FIG. 5 is a diagram for explaining the cross-sectional structure of a first electrode;

FIG. 6 is a diagram for explaining the cross-sectional structure of the optical semiconductor element;

FIG. 7 is a partially enlarged view of FIG. 1;

FIG. 8 is a cross-sectional view showing a state in which an optical semiconductor element is mounted;

FIG. 9 is a cross-sectional view of an optical semiconductor element of a first modification example;

FIG. 10 is a cross-sectional view of an optical semiconductor element of a second modification example; and

FIG. 11 is a cross-sectional view of an optical semiconductor element of a third modification example.

### DETAILED DESCRIPTION

Hereinafter, embodiments of the present disclosure will be described in detail with reference to the diagrams. In the following description, the same or equivalent elements are denoted by the same reference numerals, and repeated description thereof will be omitted.

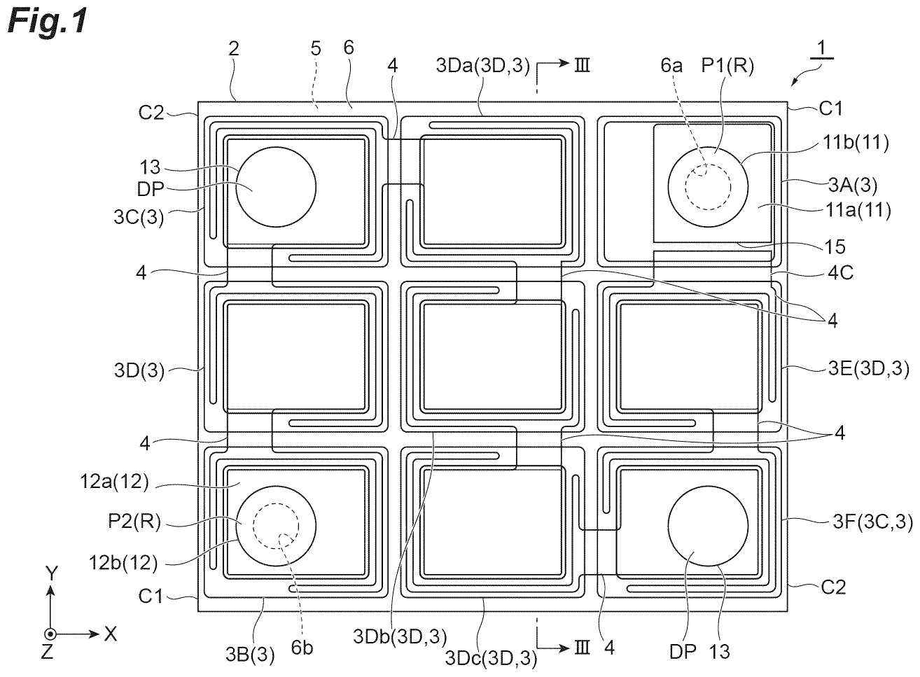

As shown in FIGS. 1 to 4, an optical semiconductor element 1 includes a substrate 2 and a plurality of (nine in this example) cells 3 formed on the substrate 2. The optical semiconductor element 1 is a light emitting element or a light receiving element. In this example, the optical semiconductor element 1 is configured as a light emitting diode (LED).

The plurality of cells 3 include a first termination cell 3A (first cell), a second termination cell 3B, a pair of dummy pad cells 3C, and a plurality of (five in this example) cells 3D other than the first termination cell 3A, the second termination cell 3B, and the dummy pad cells 3C. The plurality of cells 3 are arranged in a grid pattern so that three cells are aligned along each of the X direction and the Y direction. When viewed from the Z direction, the first termination cell 3A and the second termination cell 3B are arranged at two corners C1 located diagonally on the substrate 2, and the pair of dummy pad cells 3C are arranged at the remaining two corners C2 located diagonally on the substrate 2.

The first termination cell 3A has a first semiconductor layer 31. Each cell 3 excluding the first termination cell 3A has an optical layer 32, a second semiconductor layer 33, and a third semiconductor layer 34. That is, the layer structure of the first termination cell 3A is different from the layer structures of the other cells 3. In the optical semiconductor element 1, a plurality of cells 3 are electrically connected in series (in multiple stages) via a wiring layer 4 described later, and light is emitted from each cell 3 excluding the first termination cell 3A. That is, the first termination cell 3A is configured as a non-light-emitting cell that does not generate light, and each cell 3 excluding the first termination cell 3A is configured as a light emitting cell that generates light (configured to generate light).

The substrate 2 is a light transmissive semiconductor substrate, and is formed in a rectangular plate shape by, for example, Si, GaAs, or semi-insulating GaAs. The substrate 2 has a main surface 2a. Hereinafter, the thickness direction of the substrate 2 (direction perpendicular to the main surface 2a), the length direction of the substrate 2 (direction perpendicular to the Z direction), and the width direction of the substrate 2 (direction perpendicular to the Z direction and the X direction) will be described as a Z direction, an X direction (a predetermined direction), and a Y direction, respectively. The length of the substrate 2 (maximum length of the optical semiconductor element 1) in the X direction is, for example, 2 mm or less.

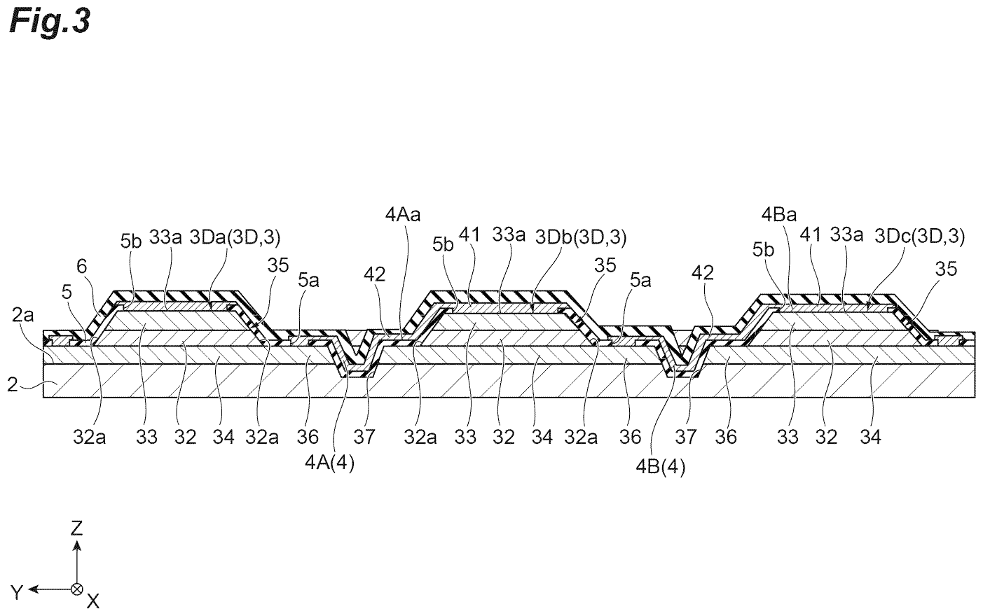

First, the configuration of the cell 3D will be described below. As described above, the cell 3D has the optical layer 32, the second semiconductor layer 33, and the third semiconductor layer 34. The third semiconductor layer 34, the optical layer 32, and the second semiconductor layer 33 are stacked in this order on the main surface 2a of the substrate 2. That is, the second semiconductor layer 33 is arranged on a side opposite to the substrate 2 (upper side in FIG. 3) with respect to the optical layer 32, and the third semiconductor layer 34 is arranged on a side of the substrate 2 (lower side in FIG. 3) with respect to the optical layer 32. The length of the cell 3D in the X direction (maximum length of the cell 3D) is, for example, 300 μm or less.

In this example, the optical layer 32 is an active layer that generates light, and is configured to generate light having a central wavelength of 3 μm or more and 10 μm or less. The optical layer 32 has, for example, a multiple quantum well structure in which a barrier layer formed of AlInAs and a well layer formed of InAsSb are alternately stacked. The optical layer 32 is formed in a rectangular shape when viewed from the Z direction, and has four straight side portions 32a. In this example, the optical layer 32 is formed in a rectangular shape having long sides along the X direction when viewed from the Z direction. The optical layer 32 may be formed in a square shape. In this example, the corners of the optical layer 32 and the cell 3D are sharp, but the corners of the optical layer 32 and the cell 3D may be rounded to have an R shape.

The second semiconductor layer 33 is a semiconductor layer of a first conductive type (for example, p-type). For example, the second semiconductor layer 33 is formed by stacking a barrier layer, a buffer layer, and a contact layer on the optical layer 32 in this order. The third semiconductor layer 34 is a semiconductor layer of a second conductive type (for example, n-type). For example, the third semiconductor layer 34 is formed by stacking a buffer layer, a contact layer, a current diffusion layer, and a barrier layer on the main surface 2a of the substrate 2 in this order. That is, the third semiconductor layer 34 has a different conductivity type from the second semiconductor layer 33. The material of each layer included in the second semiconductor layer 33 and the third semiconductor layer 34 can be appropriately selected depending on the material of the optical layer 32. As an example, the barrier layer of the second semiconductor layer 33 is formed of Al_{0.20}InAs, the buffer layer is formed of Al_{0.05}InAs, and the contact layer is formed of InAs. As an example, the buffer layer of the third semiconductor layer 34 includes three layers of GaAs, GaSb, and InAs, the contact layer and the current diffusion layer are formed of Al_{0.05}InAs, and the barrier layer is formed of Al_{0.20}InAs.

The optical layer 32 and the second semiconductor layer 33 form a mesa portion 35 formed on the third semiconductor layer 34. That is, the cell 3D has a mesa structure (pedestal structure). The mesa portion 35 is formed, for example, in a trapezoidal shape in a cross section (FIG. 3) perpendicular to the main surface 2a of the substrate 2 so as to protrude from the third semiconductor layer 34 to the side opposite to the substrate 2. Thus, the cell 3D in this example has a mesa structure including a side surface inclined with respect to the Z direction. The mesa portion 35 is formed, for example, by stacking the optical layer 32, the second semiconductor layer 33, and the third semiconductor layer 34 on the substrate 2 and then removing parts of the substrate 2, the optical layer 32, the second semiconductor layer 33, and the third semiconductor layer 34 by etching. After forming the mesa portion 35, a groove portion 37 described later is formed.

The third semiconductor layer 34 has an outer portion 36 located outside the mesa portion 35. Here, the “outside” means the side away from the center of the mesa portion 35 in the direction perpendicular to the Z direction. The outer portion 36 is formed, for example, in a rectangular ring shape so as to surround the entire circumference of the mesa portion 35 when viewed from the Z direction.

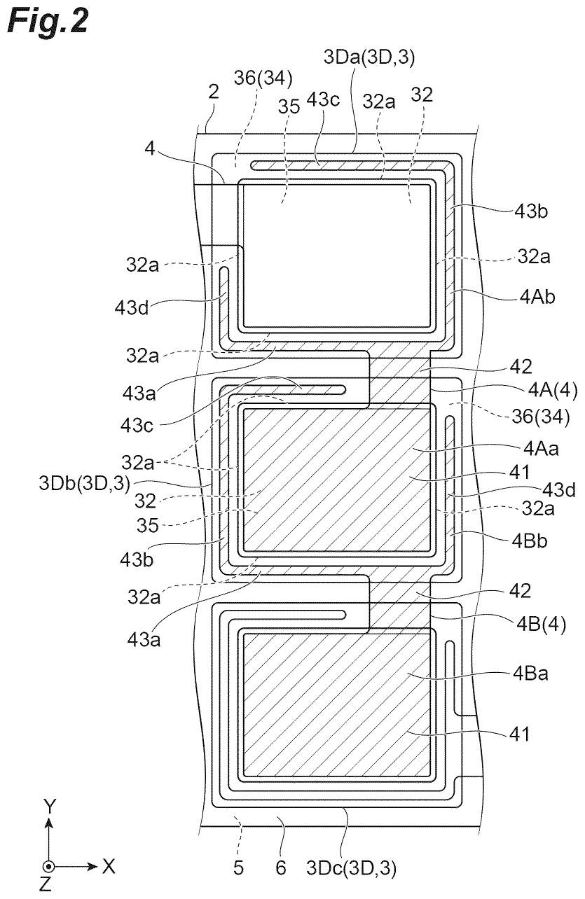

FIGS. 2 and 3 show three cells 3D that are arranged in the Y direction so as to be electrically connected in series. Hereinafter, as shown in FIGS. 2 and 3, the three cells 3D will be described as a first cell 3Da, a second cell 3Db, and a third cell 3Dc, respectively.

The third semiconductor layer 34 of the first cell 3Da and the third semiconductor layer 34 of the second cell 3Db are separated by the groove portion 37 so as to be electrically separated from each other. Similarly, the third semiconductor layer 34 of the second cell 3Db and the third semiconductor layer 34 of the third cell 3Dc are separated by the groove portion 37 so as to be electrically separated from each other. As described above, in the optical semiconductor element 1, the third semiconductor layers 34 of the adjacent cells 3 are separated by the groove portion 37 so as to be electrically separated from each other. The groove portion 37 is formed in the third semiconductor layer 34, and extends, for example, in a grid pattern so as to pass between the adjacent cells 3 when viewed from the Z direction. In this example, the groove portion 37 is formed so as to reach the inside of the substrate 2 in the Z direction. However, the groove portion 37 only needs to electrically separate the third semiconductor layers 34 of the adjacent cells 3 from each other, and the groove portion 37 does not have to be formed so as to reach the inside of the substrate 2 in the Z direction.

The first cell 3Da and the second cell 3Db are electrically connected to each other by a wiring layer 4A (wiring layer 4). Similarly, the second cell 3Db and the third cell 3Dc are electrically connected to each other by a wiring layer 4B (wiring layer 4). As described above, in the optical semiconductor element 1, the wiring layer 4 realizes the electrical connection between the cells 3. The wiring layer 4 is formed, for example, by stacking a first layer formed of Ti, a second layer formed of Pt, and a third layer formed of Au, in this order from the substrate 2 side by vapor deposition. The wiring layer 4A and the wiring layer 4B will be described below, but the other wiring layers 4 are similarly configured except for a wiring layer 4C described later, which connects the first termination cell 3A and the cell 3E to each other. The cell 3E is a cell 3 adjacent to the first termination cell 3A in the Y direction.

The wiring layer 4A is formed on the first cell 3Da and the second cell 3Db via an insulating layer 5 (second insulating layer) interposed therebetween. That is, the insulating layer 5 is formed over the first cell 3Da and the second cell 3Db, and the wiring layer 4A is formed on the insulating layer 5. The insulating layer 5 is formed of, for example, Al₂O₃, and is formed over the adjacent cells 3 and the inner surface of the groove portion 37 between the adjacent cells 3. An insulating layer 6 (first insulating layer) is formed on the insulating layer 5 and the wiring layer 4A. The insulating layer 6 is formed of, for example, Al₂O₃, and is formed over the entire surface of the substrate 2. The insulating layer 5 and the insulating layer 6 configured in this manner are transparent. In this example, a first electrode 11 and a second electrode 12, which will be described later, are visible from the outside through the insulating layer 6.

The wiring layer 4A has a first connection portion 4Aa and a first extending portion 4Ab. The first connection portion 4Aa is electrically connected to the third semiconductor layer 34 of the first cell 3Da and the second semiconductor layer 33 of the second cell 3Db. More specifically, the first connection portion 4Aa is in contact with the outer portion 36 of the third semiconductor layer 34 of the first cell 3Da through an opening 5a, and is in contact with a surface 33a of the second semiconductor layer 33 of the second cell 3Db through an opening 5b. The openings 5a and 5b are openings formed in the insulating layer 5. The surface 33a is a surface of the second semiconductor layer 33 on a side opposite to the optical layer 32, and forms a top surface of the mesa portion 35. The first connection portion 4Aa has a rectangular first portion 41 arranged on the surface 33a of the second semiconductor layer 33 of the second cell 3Db and a rectangular second portion 42 extending from the first portion 41 to reach the outer portion 36 of the third semiconductor layer 34 of the first cell 3Da. The first portion 41 is arranged on the approximately entire surface 33a. The width of the second portion 42 in the X direction is smaller than the width of the first portion 41 in the X direction.

As shown in FIG. 2, the first extending portion 4Ab extends so as to surround the outer edge of the first cell 3Da when viewed from the Z direction. Here, “extending so as to surround the outer edge of the cell” means extending along more than half of the outer edge of the cell, and is not limited to extending along the entire circumference of the outer edge of the cell. More specifically, the first extending portion 4Ab extends from the second portion 42 of the first connection portion 4Aa so as to surround the four side portions 32a of the optical layer 32 of the first cell 3Da when viewed from the Z direction. The first extending portion 4Ab is in contact with the outer portion 36 of the third semiconductor layer 34 of the first cell 3Da through the opening 5a. In FIG. 2, the wiring layer 4A and the wiring layer 4B are hatched for easy understanding.

In this example, the first extending portion 4Ab has four portions 43a, 43b, 43c, and 43d extending straight along the four side portions 32a, respectively. The portion 43a is connected to the second portion 42 of the first connection portion 4Aa. The first end of the portion 43b is connected to the first end of the portion 43a, and the portion 43b extends perpendicular to the portion 43a. The portion 43c is connected to the second end of the portion 43b, and extends perpendicular to the portion 43b and parallel to the portion 43a. The portion 43d is connected to the second end of the portion 43a, and extends perpendicular to the portion 43a and parallel to the portion 43b. In this example, the portion 43d is not connected to the portion 43c, and a gap is formed between the portions 43c and 43d when viewed from the Z direction. That is, the first extending portion 4Ab partially surrounds the four side portions 32a of the optical layer 32 of the first cell 3Da, and does not surround the entire circumference of the optical layer 32 of the first cell 3Da. The first extending portion 4Ab extends along at least a part of each of the four side portions 32a when viewed from the Z direction. As will be described later, a connection portion of another wiring layer 4 is arranged in the gap between the portions 43c and 43d.

The wiring layer 4B is formed on the second cell 3Db and the third cell 3Dc with the insulating layer 5 interposed therebetween. The wiring layer 4B has a second connection portion 4Ba and a second extending portion 4Bb. The second connection portion 4Ba is electrically connected to the third semiconductor layer 34 of the second cell 3Db and the second semiconductor layer 33 of the third cell 3Dc. More specifically, the second connection portion 4Ba is in contact with the outer portion 36 of the third semiconductor layer 34 of the second cell 3Db through the opening 5a, and is in contact with the surface 33a of the second semiconductor layer 33 of the third cell 3Dc through the opening 5b. The second connection portion 4Ba has a rectangular first portion 41 arranged on the surface 33a of the second semiconductor layer 33 of the third cell 3Dc and a rectangular second portion 42 extending from the first portion 41 to reach the outer portion 36 of the third semiconductor layer 34 of the second cell 3Db.

As shown in FIG. 2, the second extending portion 4Bb extends so as to surround the outer edge of the second cell 3Db when viewed from the Z direction. More specifically, the second extending portion 4Bb extends from the second portion 42 of the second connection portion 4Ba so as to surround the four side portions 32a of the optical layer 32 of the second cell 3Db when viewed from the Z direction. The second extending portion 4Bb is in contact with the outer portion 36 of the third semiconductor layer 34 of the second cell 3Db through the opening 5a. In this example, the second extending portion 4Bb has four portions 43a, 43b, 43c, and 43d extending straight along the four side portions 32a, respectively. The portion 43a is connected to the second portion 42 of the second connection portion 4Ba. The first end of the portion 43b is connected to the first end of the portion 43a, and the portion 43b extends perpendicular to the portion 43a. The portion 43c is connected to the second end of the portion 43b, and extends perpendicular to the portion 43b and parallel to the portion 43a. The portion 43d is connected to the second end of the portion 43a, and extends perpendicular to the portion 43a and parallel to the portion 43b. In this example, the portion 43d is not connected to the portion 43c, and a gap is formed between the portions 43c and 43d when viewed from the Z direction. That is, the second extending portion 4Bb partially surrounds the four side portions 32a of the optical layer 32 of the second cell 3Db, and does not surround the entire circumference of the optical layer 32 of the second cell 3Db. The second extending portion 4Bb extends along at least a part of each of the four side portions 32a when viewed from the Z direction. The first connection portion 4Aa of the wiring layer 4A is arranged in the gap between the portions 43c and 43d.

In the present embodiment, the first connection portion 4Aa of the wiring layer 4A does not overlap the second extending portion 4Bb of the wiring layer 4B when viewed from the Z direction. The second portion 42 of the first connection portion 4Aa of the wiring layer 4A is arranged so as to pass through the gap formed between the portions 43c and 43d of the wiring layer 4B when viewed from the Z direction.

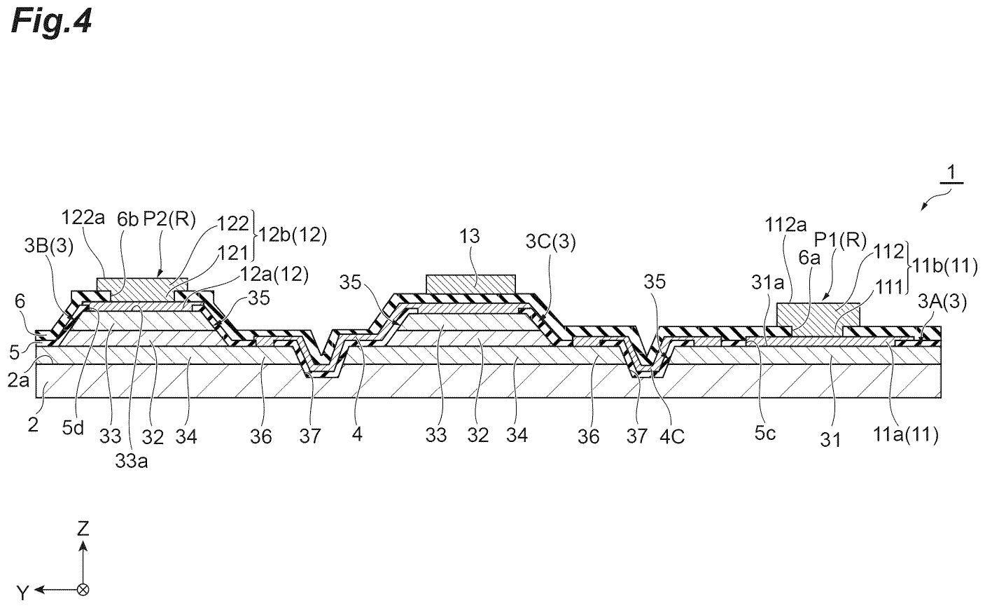

Next, the configurations of the first termination cell 3A, the second termination cell 3B, and the dummy pad cell 3C will be described with reference to FIGS. 1, 4, and 5. The first termination cell 3A, the second termination cell 3B, and the dummy pad cell 3C have the same configuration as the cell 3D except for the matters described below. In FIG. 4, for convenience of explanation, the first termination cell 3A, the dummy pad cell 3C, and the second termination cell 3B are shown side by side virtually.

The first termination cell 3A is the cell 3 arranged at one end of the electrically series connection, and the second termination cell 3B is the cell 3 arranged at the other end of the electrically series connection. The first termination cell 3A and the second termination cell 3B are electrically connected to the adjacent cell 3 by the wiring layer 4.

As described above, the first termination cell 3A has only the first semiconductor layer 31 and does not have layers corresponding to the optical layer 32 and the second semiconductor layer 33 of the other cells 3. The first semiconductor layer 31 is formed directly on the substrate 2. The first semiconductor layer 31 is a semiconductor layer of a second conductive type (for example, n-type). For example, the first semiconductor layer 31 is formed by stacking a buffer layer, a contact layer, a current diffusion layer, and a barrier layer on the main surface 2a of the substrate 2 in this order. That is, the first semiconductor layer 31 has the same conductivity type as the third semiconductor layer 34. Since the first semiconductor layer 31 has the same conductivity type as the third semiconductor layer 34, for example, the first semiconductor layer 31 and the third semiconductor layer 34 can be formed simultaneously. Therefore, the first termination cell 3A and other cells 3 can be easily formed. The first semiconductor layer 31 has the same layer structure (including material) as the third semiconductor layer 34.

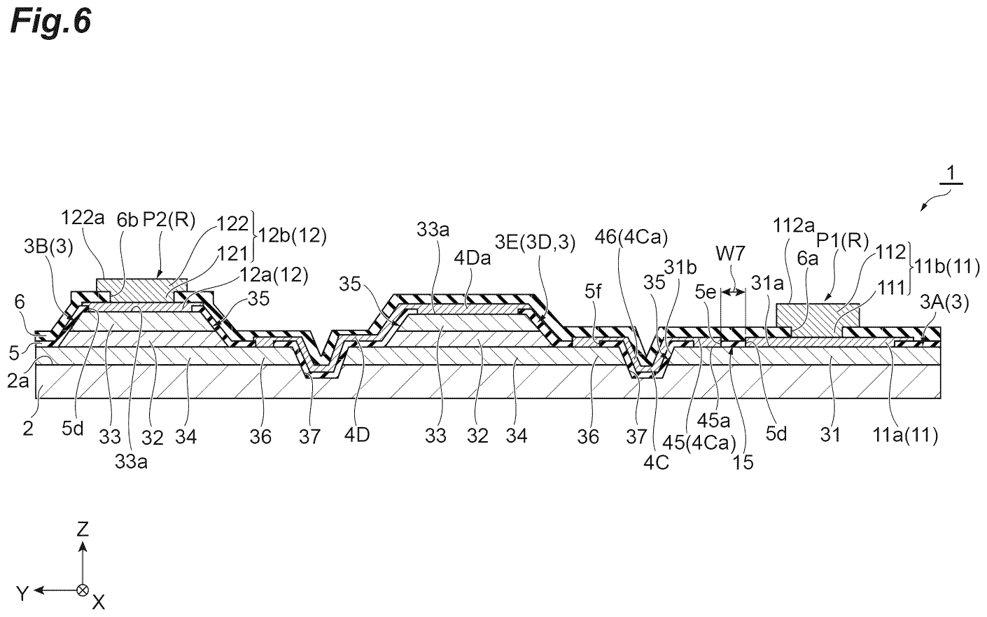

The first semiconductor layer 31 of the first termination cell 3A is not continuous with the third semiconductor layer 34 of the cell 3E (cell 3 adjacent to the first termination cell 3A) (FIG. 6). The first semiconductor layer 31 of the first termination cell 3A and the third semiconductor layer 34 of the cell 3E are separated by the groove portion 37 so as to be electrically separated from each other. The first termination cell 3A has the same shape as the cell 3E when viewed from the Z direction. More specifically, the first termination cell 3A and the cell 3E are formed in a rectangular shape having long sides parallel to the X direction when viewed from the Z direction. In this example, when viewed from the Z direction, the cells 3 other than the first termination cell 3A and the cell 3E are also formed in a rectangular shape having long sides parallel to the X direction, and all the cells 3 have the same shape.

The first semiconductor layer 31 forms the mesa portion 35 formed on the substrate 2. That is, the first termination cell 3A has a mesa structure (pedestal structure). The mesa portion 35 is formed, for example, in a trapezoidal shape in a cross section (FIG. 4) perpendicular to the main surface 2a so as to protrude from main surface 2a of the substrate 2 to the side opposite to the substrate 2. Thus, the first termination cell 3A in this example has a mesa structure including a side surface inclined with respect to the Z direction. The mesa portion 35 is formed, for example, by forming the first semiconductor layer 31 and then removing parts of the substrate 2 and the first semiconductor layer 31 by etching.

A first electrode (cathode) 11 is arranged on the top surface of the first termination cell 3A (top surface of the mesa portion 35). The first electrode 11 is electrically connected to the first semiconductor layer 31 of the first termination cell 3A. The first electrode 11 has a lower portion 11a (a second layer, a contact portion) arranged on a surface 31a of the first semiconductor layer 31 and an upper portion 11b (a first layer) arranged on the lower portion 11a. The surface 31a is a surface of the first semiconductor layer 31 on a side opposite to the substrate 2, and forms a top surface of the mesa portion 35.

The lower portion 11a is in contact with the surface 31a of the first semiconductor layer 31 (top surface of the first termination cell 3A) through an opening 5c formed in the insulating layer 5. The upper portion 11b includes a first portion 111 arranged in an opening 6a formed in the insulating layer 6 and a second portion 112 located on the first portion 111 and exposed from the opening 6a. That is, a part of the first electrode 11 is exposed to the outside through the opening 6a. The opening 6a is formed in a circular shape when viewed from the Z direction. The second portion 112 forms a first pad portion P1 for electrical connection with an external member 50 described later. A surface 112a of the second portion 112 on a side opposite to the substrate 2 is a planned contact region R with which solder comes into contact when being electrically connected to the external member 50. In this example, the entire surface 112a of the second portion 112 forms the planned contact region R.

When viewed from the Z direction, the area of the upper portion 11b is smaller than the area of the lower portion 11a, and the entire upper portion 11b is located within the outer edge of the lower portion 11a. In this example, when viewed from the Z direction, the lower portion 11a is formed in a rectangular shape, and each of the first portion 111 and the second portion 112 is formed in a circular shape. Therefore, when viewed from the Z direction, the planned contact region R is formed in a circular shape.

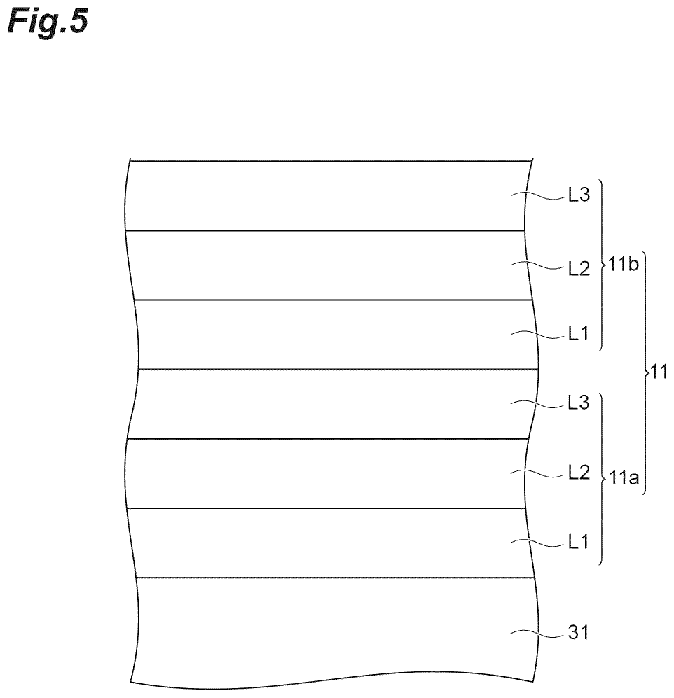

As shown in FIG. 5, the lower portion 11a is formed by stacking a first layer L1 formed of Ti, a second layer L2 formed of Pt, and a third layer L3 formed of Au on the surface 31a of the first semiconductor layer 31 in this order by vapor deposition. That is, the lower portion 11a has the same three-layer structure as the wiring layer 4 described above. Similarly to the lower portion 11a, the upper portion 11b is formed by stacking a first layer L1 formed of Ti, a second layer L2 formed of Pt, and a third layer L3 formed of Au on the third layer L3 of the lower portion 11a in this order by vapor deposition. That is, the upper portion 11b has the same three-layer structure as the lower portion 11a and the wiring layer 4. Since the second layer L2 of the upper portion 11b formed of Pt is provided, it is possible to suppress the occurrence of a situation (solder erosion, solder corrosion) in which solder flows to the third layer L3 of the lower portion 11a when the external member 50 is connected to the first pad portion P1 by solder as described later. That is, if the second layer L2 of the upper portion 11b is not provided, a phenomenon called solder erosion may occur and the solder may flow to the third layer L3 of the lower portion 11a. However, by providing the second layer L2 of the upper portion 11b formed of Pt, it is possible to prevent the solder from flowing to the third layer L3 of the lower portion 11a. Therefore, the flow of the solder can be stopped in the third layer L3 of the upper portion 11b. As a result, it is possible to satisfactorily control the shape of the solder.

The second electrode (anode) 12 is arranged on the top surface of the second termination cell 3B (top surface of the mesa portion 35). The second electrode 12 is electrically connected to the second semiconductor layer 33 of the second termination cell 3B. The second electrode 12 has a lower portion 12a arranged on the surface 33a of the second semiconductor layer 33 and an upper portion 12b arranged on the lower portion 12a. The surface 33a is a surface of the second semiconductor layer 33 on a side opposite to the substrate 2, and forms a top surface of the mesa portion 35.

The lower portion 12a is in contact with the surface 33a of the second semiconductor layer 33 (top surface of the second termination cell 3B) through an opening 5d formed in the insulating layer 5. The upper portion 12b includes a first portion 121 arranged in an opening 6b formed in the insulating layer 6 and a second portion 122 located on the first portion 121 and exposed from the opening 6b. That is, a part of the second electrode 12 is exposed to the outside through the opening 6b. The opening 6b is formed in a circular shape when viewed from the Z direction. The second portion 122 forms a second pad portion P2 for electrical connection with the external member 50 described later. A surface 122a of the second portion 122 on a side opposite to the substrate 2 is the planned contact region R with which solder comes into contact when being electrically connected to the external member 50. In this example, the entire surface 122a of the second portion 122 forms the planned contact region R.

When viewed from the Z direction, the area of the upper portion 12b is smaller than the area of the lower portion 12a, and the entire upper portion 12b is located within the outer edge of the lower portion 12a. In this example, when viewed from the Z direction, the lower portion 12a is formed in a rectangular shape, and each of the first portion 121 and the second portion 122 is formed in a circular shape. Therefore, when viewed from the Z direction, the planned contact region R is formed in a circular shape.

The lower portion 12a of the second electrode 12 has the same three-layer structure as the lower portion 11a of the first electrode 11. The upper portion 12b of the second electrode 12 has the same three-layer structure as the upper portion 11b of the first electrode 11. That is, when the external member 50 is connected to the second pad portion P2 by solder, it is possible to prevent the solder from flowing to the third layer of the lower portion 12a because the second layer formed of Pt is provided in the upper portion 12b. Therefore, the flow of the solder can be stopped in the third layer of the upper portion 12b. As a result, it is possible to satisfactorily control the shape of the solder. The lower portion 12a and the upper portion 12b configured in this manner are opaque to light generated in the optical layer 32. In this example, the lower portion 12a and the upper portion 12b reflect light generated in the optical layer 32.

When viewed from the Z direction, the area of the first electrode 11 on the top surface of the first termination cell 3A is smaller than the area of the second electrode 12 on the top surface of the second termination cell 3B. By reducing the area of the first electrode 11, it is possible to reduce the degree of the occurrence of a situation (solder erosion, solder corrosion) in which solder 40 diffuses into the first electrode 11.

A dummy electrode 13 is arranged on the top surface of the dummy pad cell 3C (top surface of the mesa portion 35). The dummy electrode 13 is arranged on the insulating layer 6 so as to overlap the second semiconductor layer 33 of the dummy pad cell 3C in the Z direction. The dummy electrode 13 has, for example, the same layer structure as the upper portion 11b of the first electrode 11. The dummy electrode 13 is electrically separated (insulated) from the optical layer 32, the second semiconductor layer 33, and the third semiconductor layer 34 of the dummy pad cell 3C by the insulating layer 6. The dummy electrode 13 forms a dummy pad portion DP. The dummy pad portion DP is formed in a circular shape when viewed from the Z direction.

The external member 50 is connected to the dummy pad portion DP by solder as in the case of the first pad portion P1 and the second pad portion P2. However, as described above, unlike the first pad portion P1 and the second pad portion P2, the dummy pad portion DP is electrically insulated from the optical layer 32, the second semiconductor layer 33, and the third semiconductor layer 34 of the dummy pad cell 3C.

Next, the wiring layer 4C (wiring layer 4) that connects the first termination cell 3A and the cell 3E to each other and the wiring layer 4D (wiring layer 4) that connects the cell 3E and the cell 3F to each other will be described with reference to FIGS. 1, 6, and 7. The cell 3E is a cell 3 adjacent to the first termination cell 3A in the Y direction, and the cell 3F is a cell 3 adjacent to the cell 3E in the Y direction. In FIG. 6, for convenience of explanation, the first termination cell 3A, the cell 3E, and the second termination cell 3B are shown side by side virtually. The wiring layers 4C and 4D are configured in the same manner as the wiring layers 4A and 4B described above except for the matters described below.

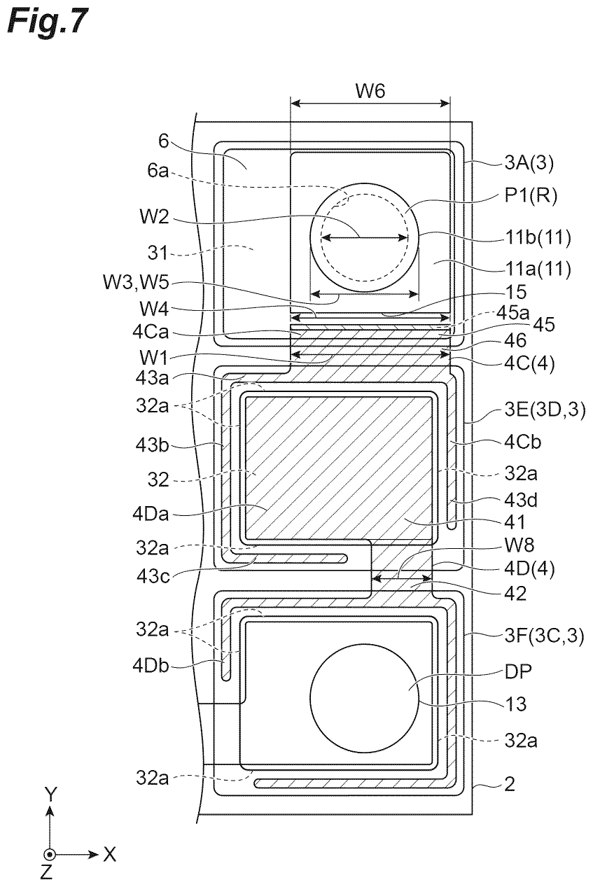

As shown in FIG. 7, the first termination cell 3A is electrically connected to the adjacent cell 3E (second cell) via the wiring layer 4C (first wiring layer). The wiring layer 4C extends from the top surface of the first termination cell 3A to the cell 3E. The cell 3E is electrically connected to the adjacent cell 3F (third cell) via the wiring layer 4D (second wiring layer). The wiring layer 4D is formed from the top surface of the cell 3E to the cell 3F.

The wiring layer 4C has a third connection portion 4Ca and a third extending portion 4Cb. The third connection portion 4Ca is a portion extending from the top surface of the first termination cell 3A to the cell 3E. The third connection portion 4Ca is arranged so as to pass from the surface 31a of the first semiconductor layer 31 to the inner surface of the groove portion 37 between the first termination cell 3A and the cell 3E and reach the outer portion 36 of the third semiconductor layer 34 of the cell 3E. The third connection portion 4Ca is electrically connected to the first semiconductor layer 31 of the first termination cell 3A and the third semiconductor layer 34 of the cell 3E. More specifically, the third connection portion 4Ca is in contact with the surface 31a of the first semiconductor layer 31 of the first termination cell 3A through an opening 5e, and is in contact with the outer portion 36 of the third semiconductor layer 34 of the cell 3E through an opening 5f. The openings 5e and 5f are openings formed in the insulating layer 5.

The third connection portion 4Ca has a rectangular first portion 45 arranged on the surface 31a of the first semiconductor layer 31 and a rectangular second portion 46 extending from the first portion 45 to the outer portion 36 of the third semiconductor layer 34 of the cell 3E. The width of the second portion 46 in the X direction is equal to the width of the first portion 45 in the X direction. The insulating layer 5 is arranged between the second portion 46 of the third connection portion 4Ca and the side surface of the first termination cell 3A (the side surface 31b of the first semiconductor layer 31). The insulating layer 5 is provided so as to reach the top surface of the first termination cell 3A (surface 31a of the first semiconductor layer 31).

As shown in FIG. 7, the third extending portion 4Cb extends so as to surround the outer edge of the cell 3E when viewed from the Z direction. More specifically, the third extending portion 4Cb extends from the second portion 46 of the third connection portion 4Ca so as to surround the four side portions 32a of the optical layer 32 of the cell 3E when viewed from the Z direction. The third extending portion 4Cb is in contact with the outer portion 36 of the third semiconductor layer 34 of the cell 3E through the opening 5f. In FIG. 7, the wiring layer 4C and the wiring layer 4D are hatched for easy understanding.

In this example, the third extending portion 4Cb has four portions 43a, 43b, 43c, and 43d, similarly to the first extending portion 4Ab of the wiring layer 4A. The portion 43d is not connected to the portion 43c, and a gap is formed between the portions 43c and 43d when viewed from the Z direction. A fourth connection portion 4Da of the wiring layer 4D, which will be described later, is arranged in the gap between the portions 43c and 43d.

The first portion 45 of the third connection portion 4Ca has a contact region 45a in contact with the surface 31a of the first semiconductor layer 31. In FIG. 7, a portion corresponding to the contact region 45a in the first portion 45 is shown by different hatching from the other portions of the first portion 45. The contact region 45a is a surface of a portion of the first portion 45, which is arranged in the opening 5e of the insulating layer 5, on the substrate 2 side. In this example, the opening 5e is formed in a rectangular shape having long sides along the X direction when viewed from the Z direction. In this example, the width of the opening 5e in the X direction is equal to the width of the first portion 45 in the X direction. When viewed from the Z direction, the shape of the contact region 45a matches the shape of the opening 5e. That is, the contact region 45a has a rectangular shape with long sides along the X direction.

The third connection portion 4Ca of the wiring layer 4C is spaced apart from the first electrode 11 on the top surface of the first termination cell 3A. More specifically, a separation portion 15 is formed between the first portion 45 of the third connection portion 4Ca and the lower portion 11a of the first electrode 11. The separation portion 15 is a space (gap) formed between the first electrode 11 and the wiring layer 4C on the top surface of the first termination cell 3A. The separation portion 15 spatially separates the first portion 45 and the lower portion 11a from each other. That is, the wiring layer 4C is not directly connected to the first electrode 11. The third connection portion 4Ca of the wiring layer 4C is electrically connected to the lower portion 11a of the first electrode 11 via the first semiconductor layer 31. The insulating layer 5 and the insulating layer 6 are arranged in the separation portion 15.

As shown in FIG. 7, the width W1 of the third connection portion 4Ca is larger than the width W2 of the opening 6a of the insulating layer 6 along the width direction (X direction in this example) of the third connection portion 4Ca. The width W1 of the third connection portion 4Ca is the maximum width of the third connection portion 4Ca in the X direction. The width direction of the third connection portion 4Ca is a direction perpendicular to the extending direction of the third connection portion 4Ca. In this example, the Y direction from the first termination cell 3A to the cell 3E is the extending direction of the third connection portion 4Ca, and the X direction perpendicular to the extending direction is the width direction of the third connection portion 4Ca. The width W2 of the opening 6a is the maximum width of the opening 6a in the X direction. In this example, the width W2 of the opening 6a is the diameter of the opening 6a. In this example, the third connection portion 4Ca is formed so as to have a uniform width, and the entire width of the third connection portion 4Ca is larger than the width W2 of the opening 6a. In addition, the width W1 of the third connection portion 4Ca is larger than the width W3 of the planned contact region R of the first electrode 11 in the X direction. The width W3 of the planned contact region R is the maximum width of the planned contact region R in the X direction. In this example, the width W3 of the planned contact region R is the diameter of the planned contact region R (surface 112a of the second portion 112).

The width W4 of the contact region 45a is larger than the width W2 of the opening 6a. The width W4 of the contact region 45a is the maximum width of the contact region 45a in the X direction along the width direction of the wiring layer 4C (third connection portion 4Ca). In this example, the width W4 of the contact region 45a is equal to the width of the opening 5e (width of the first portion 45) in the X direction. The width W4 of the contact region 45a is larger than the width W5 of the upper portion 11b of the first electrode 11. The width W5 of the upper portion 11b is the maximum width of the upper portion 11b in the X direction. In this example, the width W5 of the upper portion 11b is the diameter of the upper portion 11b.

The width W6 of a contact portion (lower portion 11a in this example) of the first electrode 11, which is in contact with the top surface of the first termination cell 3A, in the X direction is larger than the width W3 of the planned contact region R in the X direction. The width W6 of a contact portion of the first electrode 11 in contact with the top surface of the first termination cell 3A is the maximum width of the contact portion in the X direction. In this example, the width W1 of the third connection portion 4Ca and the width W4 of the contact region 45a are equal to the width W6 of the contact portion (lower portion 11a).

The width W7 (FIG. 6) of the separation portion 15 in the Y direction is smaller than the width W1 of the third connection portion 4Ca, the width W2 of the opening 6a, the width W3 of the planned contact region R, and the width W4 of the contact region 45a. The width W7 of the separation portion 15 is the minimum width of the separation portion 15 in the Y direction, and is a distance from the first portion 45 to the first electrode 11. In this example, the width W7 of the separation portion 15 is a minimum distance between the lower portion 11a of the first electrode 11 and the first portion 45 of the wiring layer 4C. The width W7 of the separation portion 15 may be, for example, about 10 μm.

The wiring layer 4D has a fourth connection portion 4Da and a fourth extending portion 4Db. The fourth connection portion 4Da has the same configuration as the first connection portion 4Aa of the wiring layer 4A, and is electrically connected to the second semiconductor layer 33 of the cell 3E and the third semiconductor layer 34 of the cell 3F. The fourth connection portion 4Da has a rectangular first portion 41 arranged on the surface 33a of the second semiconductor layer 33 of the cell 3E and a rectangular second portion 42 extending from the first portion 41 to the outer portion 36 of the third semiconductor layer 34 of the cell 3F. The fourth extending portion 4Db has the same configuration as the first extending portion 4Ab, and extends from the second portion 42 of the fourth connection portion 4Da so as to surround the outer edge of the cell 3F when viewed from the Z direction.

A portion (second portion 42) of the fourth connection portion 4Da between the cell 3E and the cell 3F does not overlap the third extending portion 4Cb of the wiring layer 4C when viewed from the Z direction. More specifically, the second portion 42 of the fourth connection portion 4Da is arranged in the gap between the portions 43c and 43d of the third extending portion 4Cb, and does not overlap the third extending portion 4Cb. The width W1 of the wiring layer 4C that connects the first termination cell 3A and the cell 3E to each other is larger than the width W8 of the wiring layer 4D that connects the cell 3E and the cell 3F to each other. More specifically, the width W1 of the third connection portion 4Ca in the wiring layer 4C is larger than the width W8 of a portion (second portion 42) of the wiring layer 4D between the cell 3E and the cell 3F. In this example, the entire width W1 of the third connection portion 4Ca is larger than the width W8 of the portion of the wiring layer 4D between the cell 3E and the cell 3F. The width W4 of the contact region 45a is larger than the width W8 of the second portion 42 in the wiring layer 4D. In addition, in this example, the width of the wiring layer 4 that connects the cells 3 other than the first termination cell 3A between these cells is the width W8.

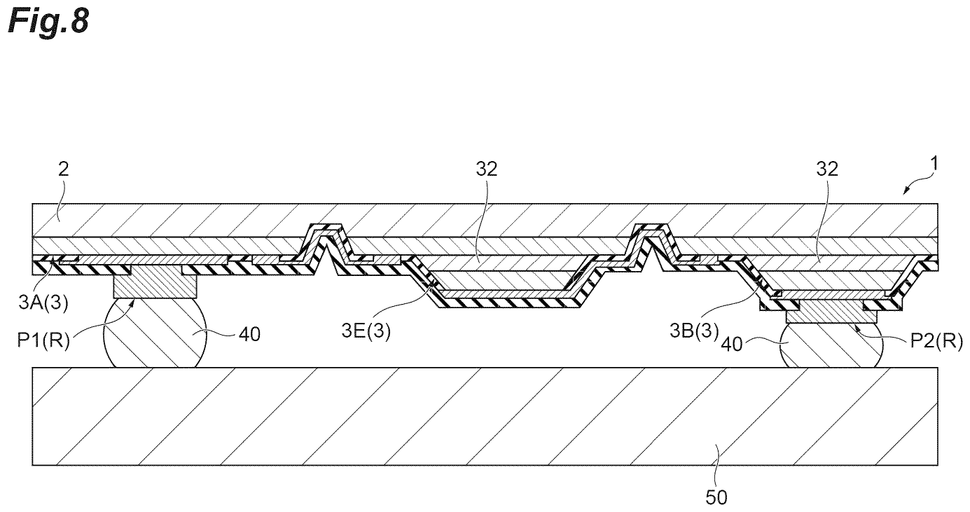

FIG. 8 is a cross-sectional view showing a state in which the optical semiconductor element 1 is mounted. FIG. 8 shows an example in which the optical semiconductor element 1 is electrically connected to the external member 50 by solder (bump, bonding material) 40. In this example, each of the first pad portion P1 (planned contact region R of the first electrode 11) and the second pad portion P2 (planned contact region R of the second electrode 12) is connected to the external member 50 by the solder 40. In addition, although not shown, the dummy pad portion DP is connected to the external member 50 by the solder 40. During the operation of the optical semiconductor element 1, a voltage is applied between the first pad portion P1 (first electrode 11) and the second pad portion P2 (second electrode 12) via the external member 50. As a result, in each cell 3 excluding the first termination cell 3A, carriers are injected into the optical layer 32 to generate light, and the generated light is emitted through the substrate 2. Instead of the solder 40, an Au bump or an In bump may be used as a bonding material.

### Functions and Effects

In the optical semiconductor element 1, the wiring layer 4C is spaced apart from the first electrode 11 on the top surface of the first termination cell 3A (surface 31a of the first semiconductor layer 31). If the first electrode 11 is electrically connected to the external member 50 by the solder 40, a phenomenon (solder erosion, solder corrosion) in which the solder 40 diffuses into the first electrode 11 may occur. However, since the wiring layer 4C is spaced apart from the first electrode 11, the diffusion of the solder 40 can be restrained at the first electrode 11. Therefore, it is possible to suppress the diffusion of the solder 40 into the wiring layer 4C. For this reason, in the optical semiconductor element 1, stable connection with the external member 50 by the solder 40 is possible. That is, if the solder 40 diffuses into the wiring layer 4C, there is a risk that the wiring layer 4C will become brittle to cause disconnection. In this regard, in the optical semiconductor element 1, the region where solder erosion can occur can be limited to only the first electrode 11, and the amount of solder 40 that diffuses into the first electrode 11 due to solder erosion can be reduced. As a result, the wiring layer 4C can be prevented from becoming brittle, and the first electrode 11 and the external member 50 can be stably connected to each other by the solder 40. In particular, in a step portion formed between the adjacent cells 3, a load is easily applied to the wiring layer 4C due to temperature cycles and the like. As a result, disconnection is likely to occur. On the other hand, in the optical semiconductor element 1, since the diffusion of the solder 40 into the wiring layer 4C can be suppressed, disconnection of the wiring layer 4C can be suppressed. In addition, in the optical semiconductor element 1, the wiring layer 4C is spaced apart from the first electrode 11 on the top surface of the first termination cell 3A, and is electrically connected to the first electrode 11 via the first semiconductor layer 31. That is, the wiring layer 4C is spaced apart from the first electrode 11 to suppress the diffusion of the solder 40 into the wiring layer 4C, and the wiring layer 4C and the first electrode 11 are electrically connected to each other via the first semiconductor layer 31. However, in this case, the electrical resistance may increase compared with a case where the wiring layer 4C is directly connected to the first electrode 11. In this regard, in the optical semiconductor element 1, the first portion 45 has the contact region 45a that is in contact with the first semiconductor layer 31, and the width W4 of the contact region 45a is larger than the width W2 of the opening 6a. Therefore, the electrical resistance can be reduced by increasing the width of the contact region 45a in contact with the first semiconductor layer 31 in the wiring layer 4C. As a result, it is possible to make a current flow satisfactorily. Therefore, according to the optical semiconductor element 1, stable connection with the external member 50 by the solder 40 is possible, and a current can flow satisfactorily.

The entire width W1 of the third connection portion 4Ca is larger than the width W2 of the opening 6a. Therefore, the electrical resistance in the wiring layer 4C can be further reduced, and it is possible to reduce the electrical resistance.

When viewed from the Z direction (thickness direction of the substrate 2), the planned contact region R has a circular shape. For example, if the planned contact region R has a rectangular shape, there is a risk that stress will concentrate at the corners. However, since the planned contact region R has a circular shape, the stress can be dispersed. As a result, it is possible to suppress the occurrence of stress concentration.

The first electrode 11 has the upper portion 11b and the lower portion 11a arranged on a side of the substrate 2 with respect to the upper portion 11b. Therefore, it is possible to suppress the diffusion of the solder 40 into the first electrode 11.

The width W4 of the contact region 45a is larger than the width W5 of the upper portion 11b. Therefore, the electrical resistance in the wiring layer 4C can be further reduced, and it is possible to make a current flow satisfactorily.

The wiring layer 4C has the same layer structure as the lower portion 11a of the first electrode 11. Therefore, for example, the wiring layer 4C and the lower portion 11a of the first electrode 11 can be formed simultaneously. As a result, the wiring layer 4C and the first electrode 11 can be formed easily.

The first electrode 11 is formed of a material containing at least Au. When the first electrode 11 is formed of a material containing Au, the solder 40 is likely to diffuse into the first electrode 11. However, according to the optical semiconductor element 1, even in such a case, the diffusion of the solder 40 into the wiring layer 4C can be suppressed.

The cell 3E includes the optical layer 32 that generates light, the second semiconductor layer 33 arranged on a side opposite to the substrate 2 with respect to the optical layer 32, and the third semiconductor layer 34 arranged on a side of the substrate 2 with respect to the optical layer 32. Therefore, light can be appropriately generated by the cell 3E.

The layer structure of the first termination cell 3A is different from the layer structure of the cell 3E. Therefore, it is possible to improve the degree of freedom in designing the layer structure of the first termination cell 3A. In addition, the structure of the first termination cell 3A can be simplified by adopting a layer structure including only the first semiconductor layer 31 arranged on the substrate 2 as the layer structure of the first termination cell 3A as in the present embodiment.

Each of the first termination cell 3A and the cell 3E has a mesa structure including a side surface inclined with respect to the Z direction. According to the optical semiconductor element 1, even when each of the first termination cell 3A and the cell 3E has a mesa structure, stable connection with the external member 50 by the solder 40 is possible.

The insulating layer 5 is arranged between the wiring layer 4C and the side surface of the first termination cell 3A (the side surface 31b of the first semiconductor layer 31), and the insulating layer 5 is provided so as to reach the top surface of the first termination cell 3A (surface 31a of the first semiconductor layer 31). Therefore, the wiring layer 4C can be reliably insulated on the side surface of the first termination cell 3A. That is, when providing the insulating layer 5 on the inclined side surface of the first termination cell 3A in order to insulate the wiring layer 4C from the substrate 2, it is difficult to control the formation location of the insulating layer 5 on the side surface. In this regard, by providing the insulating layer 5 so as to reach the top surface of the first termination cell 3A, the wiring layer 4C can be reliably insulated on the side surface of the first termination cell 3A.

The optical semiconductor element 1 includes the cell 3F formed on the substrate 2. The cell 3F is configured to generate light, and is electrically connected to the cell 3E by the wiring layer 4D. The width W4 of the contact region 45a is larger than the width W8 of a portion (second portion 42) of the wiring layer 4D between the cell 3E and the cell 3F. Therefore, the width W4 of the contact region 45a in contact with the first semiconductor layer 31 in the wiring layer 4C can be increased, and it is possible to reduce the electrical resistance.

The entire width W1 of the third connection portion 4Ca is larger than the width W8 of the portion (second portion 42) of the wiring layer 4D between the cell 3E and the cell 3F. Therefore, the electrical resistance in the wiring layer 4C can be further reduced, and it is possible to make a current flow satisfactorily.

The wiring layer 4C has the third extending portion 4Cb extending so as to surround the outer edge of the cell 3E when viewed from the Z direction. Therefore, since the third extending portion 4Cb of the wiring layer 4C extends so as to surround the outer edge of the cell 3E, a current can efficiently flow through the cell 3E.

The portion (second portion 42) of the wiring layer 4D between the cell 3E and the cell 3F does not overlap the third extending portion 4Cb of the wiring layer 4C when viewed from the Z direction. Therefore, it is possible to avoid a situation in which the wiring layer 4C and the wiring layer 4D overlap each other to generate a capacitance.

The first termination cell 3A and the cell 3E are spaced apart from each other by the groove portion 37 formed in the substrate 2. Therefore, the first termination cell 3A and the cell 3E can be spatially separated from each other.

The first termination cell 3A has the same shape as the cell 3E when viewed from the Z direction. Therefore, it is possible to prevent power from concentrating on the first termination cell 3A or the cell 3E.

The distance from the first portion 45 in the wiring layer 4C to the first electrode 11 (width W7 of the separation portion 15) is smaller than the width W2 of the opening 6a. Therefore, a current can flow satisfactorily between the wiring layer 4C and the first electrode 11.

### Modification Examples

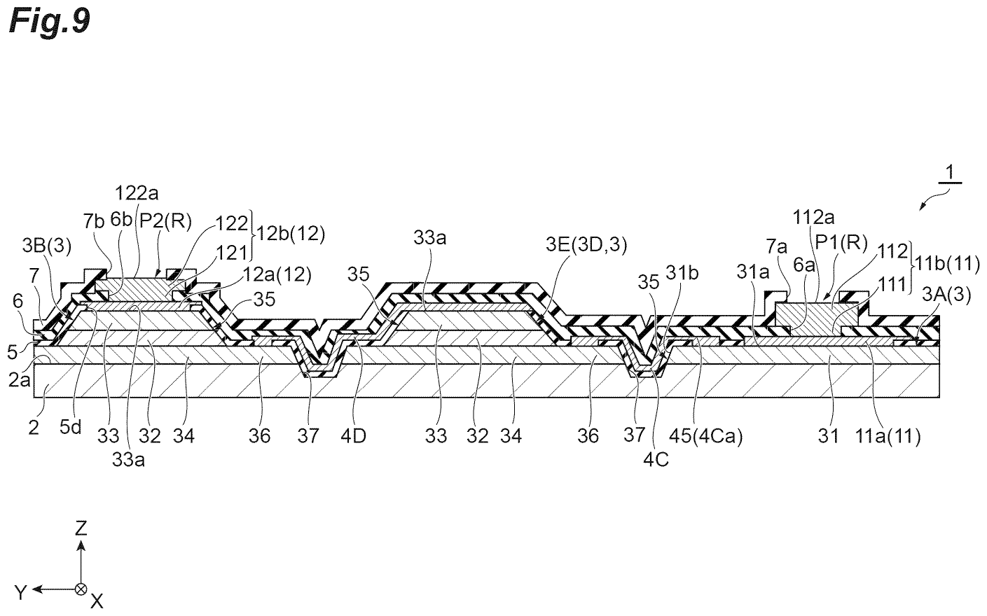

FIG. 9 is a cross-sectional view of an optical semiconductor element 1 of a first modification example. The optical semiconductor element 1 of the first modification example is configured in the same manner as the above embodiment except for the matters described below. In FIG. 9, for convenience of explanation, the first termination cell 3A, the cell 3E, and the second termination cell 3B are shown side by side virtually.

In the first modification example, the optical semiconductor element 1 includes an insulating layer 7 (third insulating layer) arranged on the insulating layer 6. The insulating layer 7 is formed of, for example, Al₂O₃, and is formed over the entire surface of the substrate 2. In this example, the insulating layer 7 is transparent, and the first electrode 11 and the second electrode 12 are visible from the outside through the insulating layer 7. The first electrode 11 is exposed to the outside of the optical semiconductor element 1 through an opening 7a formed in the insulating layer 7. More specifically, the upper portion 11b of the first electrode 11 is exposed through the opening 7a. The exposed portion in the upper portion 11b (a part of the surface 112a of the second portion 112) forms the first pad portion P1 for electrical connection with the external member 50. The exposed portion is the planned contact region R with which solder comes into contact when being electrically connected to the external member 50. In this example, the opening 7a and the planned contact region R are formed in a circular shape when viewed from the Z direction.

The second electrode 12 is exposed to the outside of the optical semiconductor element 1 through an opening 7b formed in the insulating layer 7. More specifically, the upper portion 12b of the second electrode 12 is exposed through the opening 7b. The exposed portion in the upper portion 12b (a part of the surface 122a of the second portion 122) forms the second pad portion P2 for electrical connection with the external member 50. The exposed portion is the planned contact region R with which solder comes into contact when being electrically connected to the external member 50. In this example, the opening 7b and the planned contact region R are formed in a circular shape when viewed from the Z direction.

Also in the first modification example, as in the embodiment described above, stable connection with the external member 50 by the solder 40 is possible, and it is possible to make a current flow satisfactorily. In addition, in the optical semiconductor element 1 of the first modification example, the insulating layer 7 is arranged on the insulating layer 6. The first electrode 11 is exposed to the outside through the opening 7a formed in the insulating layer 7. The planned contact region R is formed by a portion of the first electrode 11 exposed from the opening 7a. Therefore, the first electrode 11 can be reliably insulated.

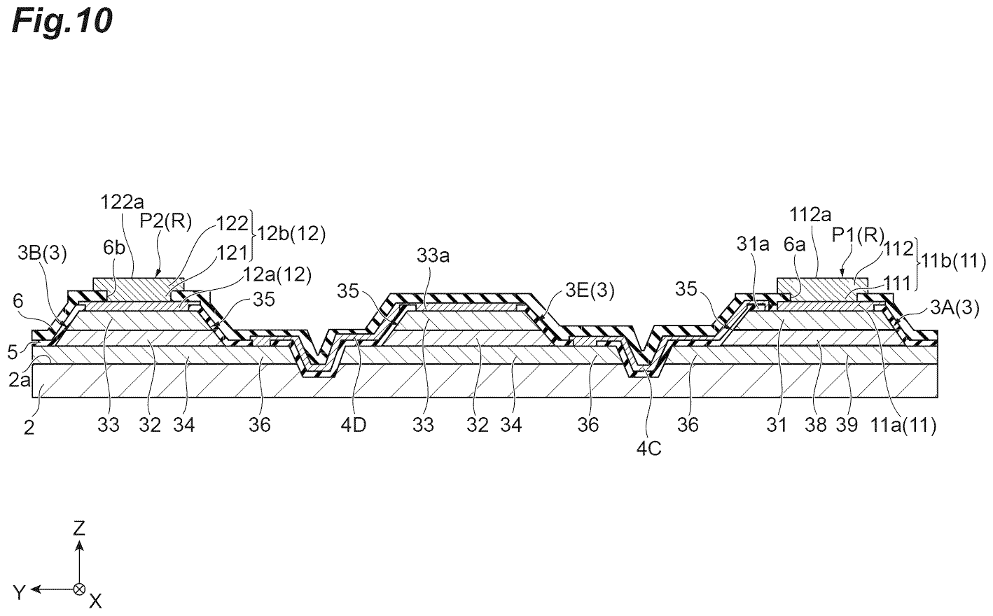

FIG. 10 is a cross-sectional view of an optical semiconductor element 1 of a second modification example. The optical semiconductor element 1 of the second modification example is configured in the same manner as the above embodiment except for the matters described below. In FIG. 10, for convenience of explanation, the first termination cell 3A, the cell 3E, and the second termination cell 3B are shown side by side virtually.

In the second modification example, the first termination cell 3A includes not only the first semiconductor layer 31 but also an intermediate layer 38 and a fourth semiconductor layer 39. That is, the first termination cell 3A has a three-layer structure similarly to the other cells 3. In other words, the layer structure of the first termination cell 3A is the same as the layer structures of the other cells 3. The intermediate layer 38 is arranged on a side of the substrate 2 with respect to the first semiconductor layer 31, and the fourth semiconductor layer 39 is arranged on a side of the substrate 2 with respect to the intermediate layer 38. That is, the fourth semiconductor layer 39, the intermediate layer 38, and the first semiconductor layer 31 are stacked in this order on the main surface 2a of the substrate 2.

The intermediate layer 38 has the same layer structure as the optical layer 32. The intermediate layer 38 has, for example, a multiple quantum well structure in which a barrier layer formed of AlInAs and a well layer formed of InAsSb are alternately stacked. In the second modification example, the first semiconductor layer 31 is a semiconductor layer of a first conductive type (for example, p-type). For example, the first semiconductor layer 31 is formed by stacking a barrier layer, a buffer layer, and a contact layer on the optical layer 32 in this order. That is, the first semiconductor layer 31 has the same conductivity type as the second semiconductor layer 33. The first semiconductor layer 31 has the same layer structure as the second semiconductor layer 33. The fourth semiconductor layer 39 is a semiconductor layer of a second conductive type (for example, n-type). For example, the fourth semiconductor layer 39 is formed by stacking a buffer layer, a contact layer, a current diffusion layer, and a barrier layer on the main surface 2a of the substrate 2 in this order. That is, the fourth semiconductor layer 39 has a different conductivity type from the first semiconductor layer 31, and has the same conductivity type as the third semiconductor layer 34. The fourth semiconductor layer 39 has the same layer structure as the third semiconductor layer 34. In the second modification example, the first semiconductor layer 31 and the intermediate layer 38 form the mesa portion 35 formed on the fourth semiconductor layer 39. The fourth semiconductor layer 39 has the outer portion 36 located outside the mesa portion 35.

Also in the second modification example, as in the embodiment described above, stable connection with the external member 50 by the solder 40 is possible, and it is possible to make a current flow satisfactorily. In addition, in the optical semiconductor element 1 of the second modification example, the first semiconductor layer 31 has the same conductivity type as the second semiconductor layer 33. Therefore, for example, the first semiconductor layer 31 and the second semiconductor layer 33 can be formed simultaneously. As a result, the first termination cell 3A and the cell 3E can be easily formed.

In the optical semiconductor element 1 of the second modification example, the layer structure of the first termination cell 3A is the same as the layer structure of the cell 3E. Therefore, it is possible to reduce the difference in height between the first termination cell 3A and the cell 3E, and the optical semiconductor element 1 can be easily mounted.

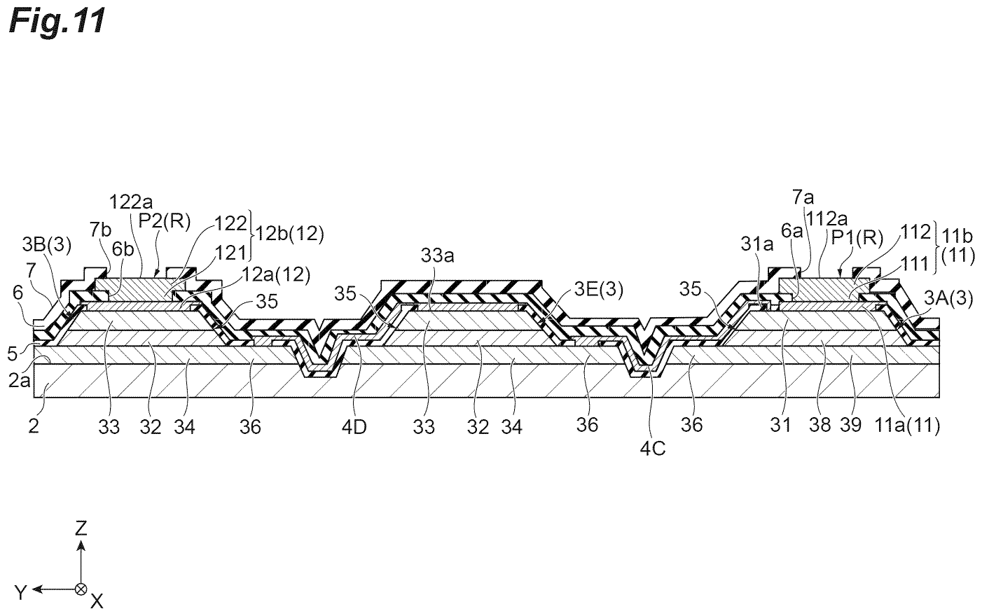

FIG. 11 is a cross-sectional view of an optical semiconductor element 1 of a third modification example. The optical semiconductor element 1 of the third modification example is configured in the same manner as the second modification example except for the matters described below. In FIG. 11, for convenience of explanation, the first termination cell 3A, the cell 3E, and the second termination cell 3B are shown side by side virtually.

In the third modification example, the optical semiconductor element 1 includes the insulating layer 7 arranged on the insulating layer 6, as in the first modification example. The insulating layer 7 is formed of, for example, Al₂O₃, and is formed over the entire surface of the substrate 2. In this example, the insulating layer 7 is transparent, and the first electrode 11 and the second electrode 12 are visible from the outside through the insulating layer 7. The first electrode 11 is exposed to the outside of the optical semiconductor element 1 through the opening 7a formed in the insulating layer 7. More specifically, the upper portion 11b of the first electrode 11 is exposed through the opening 7a. The exposed portion in the upper portion 11b (a part of the surface 112a of the second portion 112) forms the first pad portion P1 for electrical connection with the external member 50. The exposed portion is the planned contact region R with which solder comes into contact when being electrically connected to the external member 50. In this example, the opening 7a and the planned contact region R are formed in a circular shape when viewed from the Z direction.

The second electrode 12 is exposed to the outside of the optical semiconductor element 1 through the opening 7b formed in the insulating layer 7. More specifically, the upper portion 12b of the second electrode 12 is exposed through the opening 7b. The exposed portion in the upper portion 12b (a part of the surface 122a of the second portion 122) forms the second pad portion P2 for electrical connection with the external member 50. The exposed portion is the planned contact region R with which solder comes into contact when being electrically connected to the external member 50. In this example, the opening 7b and the planned contact region R are formed in a circular shape when viewed from the Z direction.

Also in the third modification example, as in the embodiment described above, stable connection with the external member 50 by the solder 40 is possible, and it is possible to make a current flow satisfactorily. In addition, in the optical semiconductor element 1 of the third modification example, the insulating layer 7 is arranged on the insulating layer 6. The first electrode 11 is exposed to the outside through the opening 7a formed in the insulating layer 7. The planned contact region R is formed by a portion of the first electrode 11 exposed from the opening 7a. Therefore, the first electrode 11 can be reliably insulated.

The present disclosure is not limited to the embodiments and their modification examples described above. For example, the materials and shapes of the respective components are not limited to the materials and shapes described above, and various materials and shapes can be adopted. For example, the width W1 of the third connection portion 4Ca may be equal to or greater than the width W2 of the opening 6a, or may be equal to the width W2 of the opening 6a. The width W1 of the third connection portion 4Ca may be equal to the width W3 of the planned contact region R of the first electrode 11. The width W1 of the third connection portion 4Ca may be larger or smaller than the width W6 of a contact portion (lower portion 11a in the above embodiment) of the first electrode 11 that is in contact with the top surface of the first termination cell 3A. The width W4 of the contact region 45a may be equal to or greater than the width W2 of the opening 6a, or may be equal to the width W2 of the opening 6a. The width W4 of the contact region 45a may be equal to the width W5 of the upper portion 11b, or may be smaller than the width W5 of the upper portion 11b. The width W6 of the lower portion 11a may be equal to the width W3 of the planned contact region R. The width W7 of the separation portion 15 may be equal to or greater than the width W1 of the third connection portion 4Ca, the width W2 of the opening 6a, and the width W3 of the planned contact region R. The width W1 of the third connection portion 4Ca and the width W4 of the contact region 45a may be equal to or less than the width W8 of a portion (second portion 42) of the wiring layer 4D between the cell 3E and the cell 3F. The third connection portion 4Ca may include a portion having a width smaller than the width W4 of the contact region 45a. As an example, the width of the second portion 46 along the X direction may be smaller than the width W4 of the contact region 45a. As another example, the width of a portion of the first portion 45, which is located outside the opening 5e, in the X direction may be smaller than the width W4 of the contact region 45a. The third connection portion 4Ca may include a portion having a width larger than the width W4 of the contact region 45a. In other words, the width W4 of the contact region 45a may be smaller than the width W1 of the third connection portion 4Ca. As an example, the width of the second portion 46 along the X direction may be larger than the width W4 of the contact region 45a. As another example, the width of a portion of the first portion 45, which is located outside the opening 5e, in the X direction may be larger than the width W4 of the contact region 45a. The third connection portion 4Ca may include a portion having a width equal to or less than the width W8 of the portion (second portion 42) of the wiring layer 4D between the cell 3E and the cell 3F.

The first portion 111 and the second portion 112 of the first electrode 11 and the first portion 121 and the second portion 122 of the second electrode 12 may be formed in any shape, such as a rectangular shape, without being limited to the circular shape. The planned contact region R of each of the first portion 111, the second portion 112, the first portion 121, and the second portion 122 may be formed in any shape, such as a rectangular shape, without being limited to the circular shape. The dummy pad portion DP may be formed in any shape, such as a rectangular shape, without being limited to the circular shape. The openings 6a and 6b formed in the insulating layer 6 and the openings 7a and 7b formed in the insulating layer 7 may be formed in any shape, such as a rectangular shape, without being limited to the circular shape.

The entire surface 112a of the second portion 112 of the first electrode 11 does not have to form the planned contact region R, and a part of the surface 112a may form the planned contact region R. The entire surface 122a of the second portion 122 of the second electrode 12 does not need to form the planned contact region R, and a part of the surface 122a may form the planned contact region R.

In the embodiment described above, the optical layer 32 has a multiple quantum well structure, but the optical layer 32 may be configured as a single layer. The material of the optical layer 32 is not limited to the example in the embodiment described above, and the optical layer 32 may be formed of a material containing at least one of InAsSb, AlInSb, and AlInAs. The optical layer 32 may be formed of a material containing Sb and In. The optical layer 32 may be formed of a material containing Sb. Even in these cases, the optical layer 32 can be configured as an active layer that generates light having a central wavelength of 3 μm or more and 10 μm or less. The optical layer 32 may be an active layer that generates light having a central wavelength of 3 μm or more and 8 μm or less, or may be an absorption layer having a maximum sensitivity wavelength of 3 μm or more and 8 μm or less. The wiring layer 4, the first electrode 11, and the second electrode 12 may be formed of a metal material other than those described above. The wiring layer 4 does not necessarily have to be formed in a layered shape.

In the embodiment described above, the second extending portion 4Bb of the wiring layer 4B partially surrounds the four side portions 32a of the optical layer 32 of the second cell 3Db, but the second extending portion 4Bb may surround the entire circumference of the optical layer 32. In other words, the second extending portion 4Bb may surround the entire four side portions 32a of the optical layer 32. For example, in the embodiment described above, the portions 43c and 43d of the second extending portion 4Bb may be connected to each other, and the second extending portion 4Bb may be formed in a rectangular ring shape when viewed from the Z direction. In this case, for example, by making the plane on which the first connection portion 4Aa of the wiring layer 4A is arranged different from the plane on which the second extending portion 4Bb of the wiring layer 4B is arranged, the first connection portion 4Aa and the second extending portion 4Bb are arranged so as to three-dimensionally cross (straddle) each other. In this case, the first connection portion 4Aa and the second extending portion 4Bb have portions overlapping each other when viewed from the Z direction. Similarly to the second extending portion 4Bb described above, the third extending portion 4Cb of the wiring layer 4C may surround the entire circumference of the optical layer 32. In this case, the third extending portion 4Cb of the wiring layer 4C and the fourth connection portion 4Da of the wiring layer 4D may have portions overlapping each other when viewed from the Z direction.

In the embodiment described above, the second extending portion 4Bb extends in two different directions (in FIG. 2, the direction surrounding the optical layer 32 clockwise and the direction surrounding the optical layer 32 counterclockwise) starting from the intersection with the second portion 42 of the second connection portion 4Ba. However, when the second extending portion 4Bb partially surrounds the four side portions 32a of the optical layer 32 of the second cell 3Db, the second extending portion 4Bb may extend in only one direction starting from the intersection with the second portion 42. Also in this case, the first connection portion 4Aa and the second extending portion 4Bb have portions overlapping each other when viewed from the Z direction. When the second extending portion 4Bb extends in two different directions starting from the intersection with the second portion 42, it is possible to shorten the length from the intersection with the second portion 42 to the distal end in the second extending portion 4Bb as compared with a case where the second extending portion 4Bb extends in only one direction. Therefore, since it is possible to increase the efficiency of carrier injection into the optical layer 32, it is possible to improve the light emission efficiency. Similarly to the second extending portion 4Bb described above, when the third extending portion 4Cb partially surrounds the four side portions 32a of the optical layer 32 of the cell 3E, the third extending portion 4Cb may extend in only one direction starting from the intersection with the second portion 46.

As another modification example, the optical semiconductor element 1 may be configured as a light receiving element. In this modification example, the optical semiconductor element 1 is configured as, for example, a photodiode. The optical layer 32 is an absorption layer that absorbs light, and is configured to have a maximum sensitivity wavelength of, for example, 3 μm or more and 10 μm or less. The optical layer 32 is configured in the same manner as the optical layer 32 of the above embodiment, for example. In each cell 3 excluding the first termination cell 3A, light incident through the substrate 2 is absorbed by the optical layer 32, and carriers are generated in the optical layer 32. The generated carriers are extracted via the first pad portion P1 (first electrode 11) and the second pad portion P2 (second electrode 12). In this manner, it is possible to detect light. Thus, each cell 3 excluding the first termination cell 3A may be configured as a light detection cell (to detect light). In this case, the first termination cell 3A is configured as a non-light detection cell that does not detect light.

According to this modification example, for the same reason as in the embodiment described above, stable connection with the external member 50 by the solder 40 is possible, and a current can be extracted satisfactorily. In addition, when the optical semiconductor element 1 is a light receiving element, if a plurality of cells 3 are electrically connected in series to each other, thermal noise can be reduced. As a result, the total noise can be reduced. In a photodiode having sensitivity in the mid-infrared region, it is particularly important how the thermal noise can be reduced. More specifically, as the number of cells 3 connected in series increases, thermal noise is suppressed. The smaller the size of the optical semiconductor element 1, the more optical semiconductor elements 1 can be connected in series.

In the embodiment described above, the mesa portion 35 is formed in a trapezoidal shape in the cross section perpendicular to the main surface 2a of the substrate 2 (FIG. 4), but the mesa portion 35 may be formed in a rectangular shape in the cross section. In this case, the side surface of the mesa portion 35 may extend along the Z direction.

The material of each component is not limited to those described above. As an example, the barrier layer of the second semiconductor layer 33 may be formed of (AlGa)_{0.20}In_{0.80}As, and the buffer layer and the contact layer of the second semiconductor layer 33 may be formed of In_{0.87}GaAs. The buffer layer of the third semiconductor layer 34 may be formed to have three layers formed of GaAs, low temperature InAs, and In_{0.87}GaAs, respectively, the contact layer and the current diffusion layer of the third semiconductor layer 34 may be formed of In_{0.87}GaAs, and the barrier layer of the third semiconductor layer 34 may be formed of (AlGa)_{0.20}In_{0.80}As. The insulating layer 5 and the insulating layer 6 may be formed of SiO₂. As another example, the substrate 2 may be formed of SI—InP. The barrier layer of the second semiconductor layer 33 may be formed of Al_{0.15}InAs, and the buffer layer and the contact layer of the second semiconductor layer 33 may be formed of InAs. The buffer layer of the third semiconductor layer 34 may be formed to have three layers formed of GaAs, low temperature InAs, and InAs, respectively, the contact layer and the current diffusion layer of the third semiconductor layer 34 may be formed of InAs, and the barrier layer of the third semiconductor layer 34 may be formed of Al_{0.15}InAs. The insulating layer 5 and the insulating layer 6 may be formed of SiN. As another example, the buffer layer of the third semiconductor layer 34 may be formed to have three layers formed of GaAs, InAs, and In_{0.87}GaAs, respectively.

The substrate 2 may be formed in a square shape, a circular shape, an elliptical shape, a honeycomb shape (hexagonal shape), a diamond shape (rhombus shape), or the like when viewed from the Z direction. The first semiconductor layer 31, the optical layer 32, the second semiconductor layer 33, the third semiconductor layer 34, and the fourth semiconductor layer 39 may be formed in a square shape, a circular shape, an elliptical shape, a honeycomb shape (hexagonal shape), a diamond shape (rhombus shape), or the like when viewed from the Z direction. The first electrode 11 and the second electrode 12 may be formed in a square shape, a circular shape, an elliptical shape, or the like when viewed from the Z direction. The first connection portion 4Aa of the wiring layer 4A may be formed in any shape without being limited to the rectangular shape. The first connection portion 4Aa does not necessarily have to be arranged on the approximately entire surface 33a, and at least a part of the first connection portion 4Aa may be arranged on the surface 33a. When the substrate 2 is formed in a rectangular shape when viewed from the Z direction and the cell 3 (optical layer 32) is formed in a rectangular shape when viewed from the Z direction, the cell 3 can be efficiently arranged on the substrate 2. An insulating layer may be formed between the substrate 2 and the first semiconductor layer 31.

The first termination cell 3A and the second termination cell 3B do not necessarily have to be arranged diagonally on the substrate 2 when viewed from the Z direction, and may be arranged at any position. The dummy pad cell 3C may not be provided.

The number of cells 3 is not limited to the above example. The plurality of cells 3 only need to include at least two cells. For example, the plurality of cells 3 may include only the first termination cell 3A, the second termination cell 3B, and the cell 3E. In this case, the first termination cell 3A is electrically connected to the cell 3E, and the cell 3E is electrically connected to the second termination cell 3B. Alternatively, the plurality of cells 3 may include only the first termination cell 3A and the second termination cell 3B. In this case, the first termination cell 3A and the second termination cell 3B are electrically connected to each other.

The cell 3 in which the first electrode 11 is provided may not be the first termination cell 3A, and the first electrode 11 may be provided in the cell 3 other than the first termination cell 3A. That is, the cell 3 in which the first electrode 11 is provided does not necessarily have to be arranged at the end of the electrical series connection. Similarly, the cell 3 in which the second electrode 12 is provided may not be the second termination cell 3B, and the second electrode 12 may be provided in the cell 3 other than the second termination cell 3B. That is, the cell 3 in which the second electrode 12 is provided does not necessarily have to be arranged at the end of the electrical series connection. The plurality of cells 3 may not be electrically connected in series, and may include portions connected in parallel, for example.

As described above, the first semiconductor layer 31 included in the cell 3 in which the first electrode 11 is provided may be a p-type semiconductor layer or an n-type semiconductor layer. In addition, in the second and third modification examples, the fourth semiconductor layer 39 included in the cell 3 in which the first electrode 11 is provided may be a semiconductor layer having a different conductivity type from the first semiconductor layer 31, and may be a p-type semiconductor layer or an n-type semiconductor layer.

The first electrode 11 may have only one of the upper portion 11b and the lower portion 11a. For example, the first electrode 11 may have only the upper portion 11b without having the lower portion 11a. In this case, the first portion 111 of the upper portion 11b is in contact with the top surface of the first termination cell 3A (surface 31a of the first semiconductor layer 31), and is electrically connected to the first portion 45 of the third connection portion 4Ca via the first semiconductor layer 31. The separation portion 15 is formed between the first portion 111 of the upper portion 11b and the first portion 45 of the third connection portion 4Ca. In addition, the first electrode 11 may have only the lower portion 11a without having the upper portion 11b. In this case, the lower portion 11a is exposed to the outside of the optical semiconductor element 1 through the opening 6a formed in the insulating layer 6. The exposed portion of the lower portion 11a forms the planned contact region R of the first electrode 11. Similarly to the first electrode 11, the second electrode 12 may have only one of the upper portion 12b and the lower portion 12a.

The first electrode 11 may not overlap the insulating layer 6 when viewed from the Z direction, and may be formed only inside the opening 6a. That is, when viewed from the Z direction, the outer edge of each of the upper portion 11b and the lower portion 11a may be located inside the opening 6a. Similarly to the first electrode 11, the second electrode 12 may not overlap the insulating layer 6 when viewed from the Z direction, and may be formed only inside the opening 6b.

Each of the upper portion 11b, the lower portion 11a, the upper portion 12b, and the lower portion 12a may not include one or more layers of the first layer L1 formed of Ti, the second layer L2 formed of Pt, and the third layer L3 formed of Au, and may include a layer formed of another metal material. For example, each of the upper portion 11b, the lower portion 11a, the upper portion 12b, and the lower portion 12a may further include a fourth layer, which is formed on the third layer L3 and is formed of Ni, and a fifth layer, which is formed on the fourth layer and is formed of Au. Each of the first electrode 11 and the second electrode 12 may be formed of a material that does not contain Au. Each of the first electrode 11 and the second electrode 12 may be composed of one metal layer. The wiring layer 4 may have a layer structure different from that of the lower portion 11a.

In the embodiments described above, the insulating layer 5 is arranged so as to pass from the inner surface of the groove portion 37 to the side surface of the first termination cell 3A and reach the top surface of the first termination cell 3A. However, the insulating layer 5 does not need to reach the top surface of the first termination cell 3A, and may remain, for example, on the side surface of the first termination cell 3A.

The groove portion 37 may not be formed between the first termination cell 3A and the cell 3E, and the first semiconductor layer 31 of the first termination cell 3A and the third semiconductor layer 34 of the cell 3E may be continuous. The first termination cell 3A may have a different shape from the cell 3E when viewed from the Z direction. The wiring layer 4 does not need to have an extending portion. For example, the wiring layer 4C may have only the third connection portion 4Ca without having the third extending portion 4Cb.

What is claimed is:

1. An optical semiconductor element, comprising:
a substrate; and
a first cell and a second cell formed on the substrate,
wherein the first cell includes at least a first semiconductor layer,
the second cell is configured to generate or detect light,
a first electrode electrically connected to the first semiconductor layer is arranged on a top surface of the first cell,
the first cell and the second cell are electrically connected to each other by a first wiring layer extending from the top surface of the first cell to the second cell,
a first insulating layer is arranged on the top surface of the first cell, and the first electrode is exposed to outside through an opening formed in the first insulating layer,
the first wiring layer is spaced apart from the first electrode on the top surface of the first cell, and is electrically connected to the first electrode via the first semiconductor layer,
a portion of the first wiring layer arranged on the top surface of the first cell includes a contact region in contact with the first semiconductor layer, and
a width of the contact region in a predetermined direction along a width direction of the first wiring layer is equal to or greater than a width of the opening in the predetermined direction.

2. The optical semiconductor element according to claim 1,
wherein an entire width of a portion of the first wiring layer extending from the top surface of the first cell to the second cell is equal to or greater than the width of the opening in the predetermined direction.

3. The optical semiconductor element according to claim 1,
wherein the first electrode includes a planned contact region with which solder comes into contact when being electrically connected to an external member, and
the planned contact region has a circular shape when viewed from a thickness direction of the substrate.

4. The optical semiconductor element according to claim 1,
wherein the first electrode includes a first layer and a second layer arranged on a side of the substrate with respect to the first layer.

5. The optical semiconductor element according to claim 4,
wherein the width of the contact region in the predetermined direction is equal to or greater than a width of the first layer in the predetermined direction.

6. The optical semiconductor element according to claim 4,
wherein the first wiring layer has the same layer structure as the second layer of the first electrode.

7. The optical semiconductor element according to claim 1,
wherein the first electrode is formed of a material containing at least Au.

8. The optical semiconductor element according to claim 1,
wherein the second cell includes an optical layer that is an active layer for generating light or an absorption layer for absorbing light, a second semiconductor layer arranged on a side opposite to the substrate with respect to the optical layer, and a third semiconductor layer arranged on a side of the substrate with respect to the optical layer.

9. The optical semiconductor element according to claim 8,
wherein a layer structure of the first cell is different from a layer structure of the second cell.

10. The optical semiconductor element according to claim 8,
wherein a layer structure of the first cell is the same as a layer structure of the second cell.

11. The optical semiconductor element according to claim 1,
wherein each of the first cell and the second cell has a mesa structure including a side surface inclined with respect to a thickness direction of the substrate.

12. The optical semiconductor element according to claim 1,
wherein a second insulating layer is arranged between the first wiring layer and a side surface of the first cell, and
the second insulating layer is provided so as to reach the top surface of the first cell.

13. The optical semiconductor element according to claim 1, further comprising:
a third cell formed on the substrate,
wherein the third cell is configured to generate or detect light and is electrically connected to the second cell by a second wiring layer, and
the width of the contact region in the predetermined direction is larger than a width of a portion of the second wiring layer between the second cell and the third cell.

14. The optical semiconductor element according to claim 13,
wherein an entire width of a portion of the first wiring layer extending from the top surface of the first cell to the second cell is larger than the width of the portion of the second wiring layer between the second cell and the third cell.

15. The optical semiconductor element according to claim 13,
wherein the first wiring layer includes an extending portion that extends so as to surround an outer edge of the second cell when viewed from a thickness direction of the substrate.

16. The optical semiconductor element according to claim 15,
wherein a portion of the second wiring layer between the second cell and the third cell does not overlap the extending portion of the first wiring layer when viewed from the thickness direction of the substrate.

17. The optical semiconductor element according to claim 1,
wherein the first cell and the second cell are spaced apart from each other by a groove portion formed in the substrate.

18. The optical semiconductor element according to claim 1,
wherein the first cell has the same shape as the second cell when viewed from a thickness direction of the substrate.

19. The optical semiconductor element according to claim 1,
wherein the first electrode includes a planned contact region with which solder comes into contact when being electrically connected to an external member,
a third insulating layer is arranged on the first insulating layer, and the first electrode is exposed to outside through an opening formed in the third insulating layer, and
the planned contact region is formed by a portion of the first electrode exposed from the opening formed in the third insulating layer.

20. The optical semiconductor element according to claim 1,
wherein a distance from a portion of the first wiring layer arranged on the top surface of the first cell to the first electrode is smaller than a width of the opening in the predetermined direction.
